(19) United States
(12) Patent Application Publication
(10) Pub. No.: US 2026/0316150 A1
(43) Pub. Date: Oct. 15, 2026

(54) FOUNDRY SAND RECLAMATION APPARATUS AND FOUNDRY SAND RECLAMATION METHOD

(71) Applicant: TOYOTA JIDOSHA KABUSHIKI KAISHA, Toyota-shi (JP)

(72) Inventors: Shoko HORI, Toyota-shi (JP); Taishiro TANI, Miyoshi-shi (JP); Shogo IZUMI, Toyota-shi (JP)

(73) Assignee: TOYOTA JIDOSHA KABUSHIKI KAISHA, Toyota-shi (JP)

(21) Appl. No.: 19/637,670

(22) Filed: Apr. 2, 2026

(30) Foreign Application Priority Data
Apr. 10, 2025 (JP) 2025-064756

(51) Int. Cl. B22C 5/08; B22C 5/18

(52) U.S. Cl. CPC B22C 5/08; B22C 5/185

(57) ABSTRACT

A foundry sand reclamation apparatus for reclaiming foundry sand from a foundry sand composition containing foundry sand and a water-soluble binder, includes: a processing apparatus including a vessel into which a foundry sand composition and an aqueous medium are charged and an agitating apparatus configured to perform agitation and mixing of the foundry sand composition and the aqueous medium charged into the vessel; a drainage apparatus configured to perform draining of at least a portion of the liquid component from a mixture of the foundry sand composition and the aqueous medium present in the vessel after agitation and mixing thereof are performed; and a drying apparatus configured to perform drying of a residue including the foundry sand remaining in the vessel after the draining is performed, in which the drying apparatus performs drying of the residue while the residue is being agitated using the agitating apparatus.

### CROSS REFERENCE TO RELATED APPLICATIONS

This application is based upon and claims the benefit of priority from Japanese patent application No. 2025-064756, filed on April 10, 2025, the disclosure of which is incorporated herein in its entirety by reference.

### BACKGROUND

The present disclosure relates to a foundry sand reclamation apparatus and a foundry sand reclamation method.

As a molding method for manufacturing molded products (metal product) by injecting molten metal into a mold configured of an upper mold, a lower mold and, if necessary, a core, and cooling and solidifying the molten metal, there is a sand molding method using a foundry sand composition containing foundry sand (particulate refractory aggregate) and a binder as a material of the mold.

Conventionally, foundry sand composition is recovered from a mold used for molding, subjected to a reclamation treatment for removing the binder, and used again in molding as reclamation foundry sand.

Binders used in molds are roughly classified into organic binders such as phenolic resins and furan resins and inorganic binders such as sodium silicate (water glass). In general, inorganic binders are preferable because they have less odor and CO₂ emissions during molding and disintegration, but removal thereof from the surface of foundry sand is not easy.

As one method for reclaiming foundry sand, there is a wet method including a washing step of adding an aqueous medium (preferably water) to a foundry sand composition reclaimed from the mold used for molding and then performing agitation and mixing, thereby the water-soluble inorganic binder adhering to foundry sand is dissolved in the aqueous medium (for example, claim 1 of Patent Literature 1).

In this method, after the washing step, it is necessary to perform a separation step of separating the wet foundry sand from the aqueous medium in which the water-soluble inorganic binder is dissolved, and a drying step of drying the wet foundry sand obtained after the separation step.

In Patent Literature 1, the washing step is performed in a sealable vessel with an agitating function as shown in FIG. 1 of Patent Literature 1. After the washing step is performed, a separation step of taking out the content from the vessel, and filtering the content that has been taken out, to thereby separate the content into the wet foundry sand and the aqueous medium in which the water-soluble inorganic binder is dissolved (paragraph 0030). Finally, a drying step of drying the wet foundry sand is performed (paragraph 0031).

[Patent Literature 1] Japanese Unexamined Patent Application Publication No. 2016-129897

### SUMMARY

In the above-mentioned conventional reclamation method, the washing step, the separation step, and the drying step are performed using different apparatuses for the respective steps. Since the content taken out from the vessel after the washing step is wet sand containing an aqueous medium, the handling property of the content is poor. Therefore, work such as taking out the content from vessel and conveying the content for the next step consume time, labor, and cost.

The present disclosure has been made in view of the above circumstances, and an object of the present disclosure to provide a foundry sand reclamation apparatus and a foundry sand reclamation method each adapted to efficiently implement a washing step, a separation step, and a drying step.

According to the present disclosure,
a foundry sand reclamation apparatus for reclaiming foundry sand from a foundry sand composition containing foundry sand and a water-soluble binder, includes:
a vessel into which the foundry sand composition and an aqueous medium are charged;
an agitating apparatus configured to perform agitation and mixing of the foundry sand composition and the aqueous medium charged into the vessel;
a drainage apparatus configured to perform draining of at least a portion of the liquid component from a mixture of the foundry sand composition and the aqueous medium present in the vessel after agitation and mixing thereof are performed; and
a drying apparatus configured to perform drying of a residue including the foundry sand remaining in the vessel after the draining is performed, the drying apparatus including a heating or temperature control apparatus configured to perform heating or controlling of a temperature inside the vessel and/or a decompression apparatus configured to perform decompression inside the vessel, in which
the drying apparatus performs drying of the residue while the residue is being agitated using the agitating apparatus.

According to the present disclosure,
a foundry sand reclamation method for reclaiming foundry sand from a foundry sand composition containing foundry sand and a water-soluble binder, includes:
a step (S1) of performing charging of the foundry sand composition and an aqueous medium into a vessel;
a step (S2) of performing agitation and mixing of the foundry sand composition and the aqueous medium charged into the vessel;
a step (S3) of performing draining of at least a portion of the liquid component from a mixture of the foundry sand composition and the aqueous medium present in the vessel after the step (S2); and
a step (S4) of performing drying of a residue containing the foundry sand remaining in the vessel after the step (S3) while the residue is being agitated.

With the foundry sand reclamation apparatus and the foundry sand reclamation method according to the present disclosure, the washing step, the separation step, and the drying step can be efficiently implemented in one vessel.

According to the technique of the present disclosure, it is not necessary to take out the wet sand containing the aqueous medium having poor handling properties from the vessel after the washing step, and work that consume time, labor, and cost, such as taking out the wet sand from the vessel and conveying the wet sand for the next step, are unnecessary.

According to the technique of the present disclosure, the polishing treatment of the foundry sand can be performed simultaneously with the drying step and/or after the drying step in the same vessel, as necessary.

According to the technique of the present disclosure, the obtained reclaimed foundry sand can be cooled in the same vessel, if necessary.

According to the technique of the present disclosure, all steps necessary for reclaiming foundry sand from a foundry sand composition containing foundry sand and a water-soluble binder can be efficiently implemented in one vessel.

According to the present disclosure, it is possible to provide a foundry sand reclamation apparatus and a foundry sand reclamation method each adapted to efficiently implement a washing step, a separation step, and a drying step.

The above and other objects, features and advantages of the present disclosure will become more fully understood from the detailed description given hereinbelow and the accompanying drawings.

### BRIEF DESCRIPTION OF DRAWINGS

FIG. 1 is an overall block diagram of a foundry sand reclamation apparatus according to an embodiment of the present disclosure;

FIG. 2 is a schematic side view of a processing apparatus according to an embodiment of the present disclosure;

FIG. 3 is a schematic cross-sectional view of a solid-liquid phase separation; and

FIG. 4 is a flowchart of a foundry sand reclamation method according to an embodiment of the present disclosure.

### DESCRIPTION OF EMBODIMENTS

### Foundry sand reclamation apparatus and foundry sand reclamation method

A foundry sand reclamation apparatus and a foundry sand reclamation method according to an embodiment of the present disclosure will be described with reference to the drawings.

A foundry sand reclamation apparatus 1 according to the present embodiment is an apparatus for reclamation of foundry sand from a foundry sand composition containing at least one kind of foundry sand and at least one kind of water-soluble binder.

A foundry sand composition may be an unmolded material before molding, an unused material reclaimed from an unused mold, a used material reclaimed from a used mold, or a combination thereof.

Foundry sand is a known particulate refractory aggregate and examples thereof include general sand such as silica sand; mountain sand; special sand such as alumina sand, olivine sand, zircon sand, and chromite sand; synthetic sand such as mullite sand; and slag sand.

As for the water-soluble binder, water-soluble inorganic binders are preferred because of the low odor and CO₂ emission during molding and disintegration. A well-known water-soluble inorganic binder may be used and examples thereof include silicic acid compounds such as sodium silicate (water glass), potassium silicate, sodium metasilicate, potassium metasilicate, lithium silicate, ammonium silicate, colloidal silica, and alkyl silicates.

Foundry sand compositions may include at least one additive other than foundry sand and a water-soluble binder.

The amount of a water-soluble binder (in the case of using more than one kind, the total amount) in a foundry sand composition is not particularly limited, and may be equal to or greater than 1 mass% and equal to or lower than 10 mass% based on 100 mass% foundry sand (in the case of using more than one kind, the total amount). The lower limit is more preferably 2 mass%, particularly preferably 3 mass%. The upper limit is more preferably 8 mass%, particularly preferably 7 mass%, and most preferably 5 mass%.

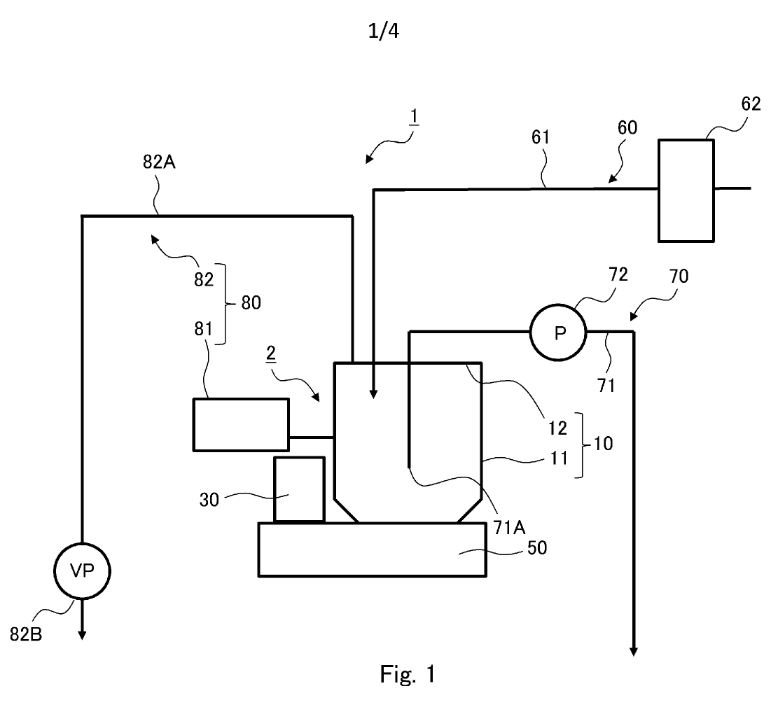

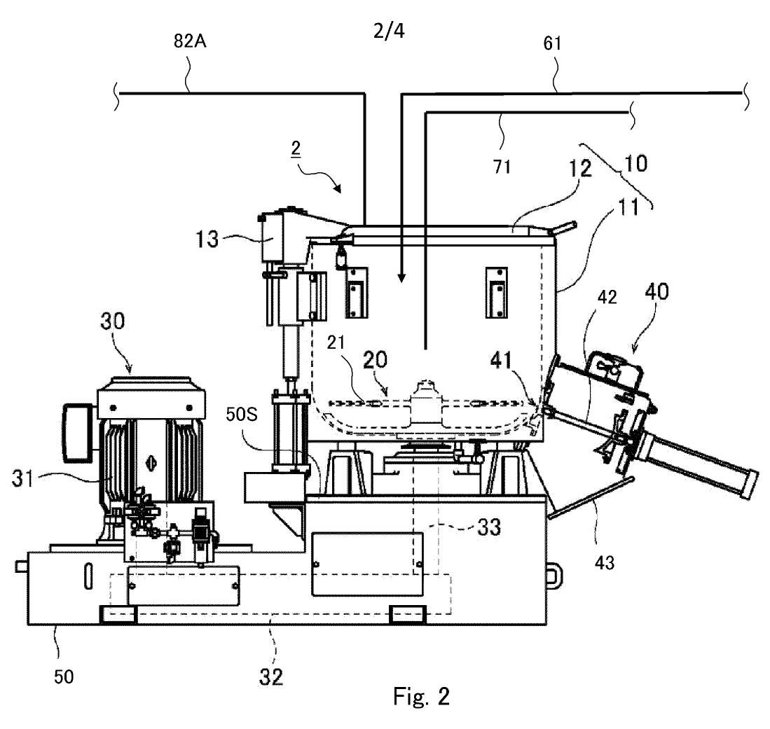

As shown in FIGS. 1 and 2, the foundry sand reclamation apparatus 1 includes a processing apparatus 2 including a vessel 10 into which a foundry sand composition and an aqueous medium are charged, and an agitating apparatus 20 configured to perform agitation and mixing of the foundry sand composition and the aqueous medium charged into the vessel 10.

The foundry sand reclamation apparatus 1 first performs a charging step (Step (S1)) of charging a foundry sand composition and an aqueous medium into the vessel 10.

The vessel 10 is made of a metallic material such as stainless steel, and includes a bottomed cylindrical (preferably bottomed cylindrical) vessel main body 11 having an opening at an upper end thereof, and an openable/closable upper lid 12, and is preferably a sealable vessel. In the drawings, reference numeral 13 denotes an upper lid support member.

The agitating apparatus 20 may include a plurality of agitation blades 21 rotatably mounted near an inner bottom surface of the vessel main body 11.

The processing apparatus 2 may include a driving unit 30 for driving the agitating apparatus 20. The driving unit 30 may include a motor unit (driving source) 31, a power transmission mechanism 32, and a shaft 33.

The processing apparatus 2 may include a base unit 50 for housing the power transmission mechanism 32 of the driving unit 30 and a part of the shaft 33, with the vessel 10 disposed on the top surface 50S thereof.

The foundry sand reclamation apparatus 1 may optionally include a foundry sand composition supply apparatus (not shown), such as a hopper, for supplying a foundry sand composition into the vessel 10.

The foundry sand reclamation apparatus 1 may optionally include a water-based medium supply apparatus 60 for supplying an aqueous medium into the vessel 10.

The water-based medium supply apparatus 60 may include a liquid supply tube 61 for supplying an aqueous medium into the vessel 10. The liquid supply tube 61 is connected to the vessel 10 and preferably to the upper lid 12 of the vessel 10. The liquid supply tube 61 is preferably partially inserted into the vessel 10.

The water-based medium supply apparatus 60 may further include a heating or temperature control apparatus 62 for heating or controlling the temperature of the aqueous medium supplied into the liquid supply tube 61 and/or flowing through the liquid supply tube 61.

The water-based medium supply apparatus 60 may further optionally include at least one other element such as valves, flow meters, and pumps.

The aqueous medium may include water, alcohols, combinations thereof, and the like, with water being preferred from the viewpoint of cost and environment. The aqueous medium may optionally include at least one additive. The water content in the aqueous medium is preferably equal to or greater than 90 wt% and equal to or lower than 100 wt%. The lower limit is more preferably 95 wt%, and particularly preferably 98 wt%.

Unless otherwise specified, the preferred temperature conditions in the following description are those where the water content in the aqueous medium is equal to or greater than 90 wt%.

The temperature of the aqueous medium supplied into the vessel 10 is preferably equal to or greater than 40℃ and equal to or lower than 100℃ from the viewpoint of improving the removal efficiency of a water-soluble binder from the foundry sand. The lower limit is more preferably 50℃, further more preferably 60℃, even more preferably 70℃, particularly preferably 80℃, and most preferably 90℃. The upper limit is more preferably 99℃, further more preferably 98℃, particularly preferably 97℃, and most preferably 95℃.

The amount of the aqueous medium to be charged into the vessel 10 is not particularly limited, and is preferably equal to or greater than 0.3 L and equal to or lower than 1.0L per 1kg of the foundry sand composition from the viewpoint of improving the removal efficiency of a water-soluble binder from the foundry sand. The lower limit is more preferably 0.4L, and particularly preferably 0.5L. The upper limit is more preferably 0.9L, and particularly preferably 0.8L.

The total volume of the foundry sand composition and the aqueous medium to be charged into the vessel 10 is not particularly limited, and is preferably equal to or greater than 20% and equal to or lower than 90% with respect to 100% of the volume of the vessel 10. The lower limit is more preferably 30%, particularly preferably 40%, and most preferably 50%. The upper limit is more preferably 80%, and particularly preferably 70%.

In the foundry sand reclamation apparatus 1, the foundry sand composition charged into the vessel 10 and the aqueous medium are agitated and mixed using the agitating apparatus 20. By this operation, a water-soluble binder adhering to the foundry sand is dissolved in the aqueous medium to thereby perform the washing step (Step (S2)) of removing the water-soluble binder from the foundry sand.

In this method, unlike the method of physically removing a water-soluble binder adhering to foundry sand by impact, friction or the like, the water-soluble binder can be removed from the foundry sand even with a relatively weak force, thereby reducing damage to the foundry sand.

From the viewpoint of improving the removal efficiency of a water-soluble binder, it is preferable to implement the washing step (Step (S2)) while the temperature inside the vessel 10 is being heated or controlled using a heating or temperature control apparatus 81. The washing step (Step (S2)) can be implemented under atmospheric pressure or under a pressurized state.

The temperature inside the vessel 10 while the washing step (Step (S2)) is being implemented is not particularly limited, and is preferably equal to or greater than 40℃ and equal to or lower than 100℃ under normal pressure conditions. The lower limit value is more preferably 50℃, further more preferably 60℃, even more preferably 70℃, particularly preferably 80℃, and most preferably 90℃. The upper limit value is more preferably 99℃, further more preferably 98℃, particularly preferably 97℃, and most preferably 95℃. In the case the vessel 10 is a closed vessel, the inside of the vessel 10 may be heated to 100℃ or higher (for example, equal to or greater than 100℃ and equal to or lower than 110℃).

The temperature inside the vessel 10 while the washing step (Step (S2)) is being implemented is preferably equal to or greater than 100℃ and equal to or lower than 120℃ under pressurized conditions.

The higher the temperature of the aqueous medium, the more easily the water-soluble binder is dissolved in the aqueous medium, which is preferable.

By implementing the washing step (Step (S2)) under the condition in which the temperature of the aqueous medium is high, even if there are pores and/or irregularities in the surface of the foundry sand, the water-soluble binder is easily removed from the foundry sand, which is preferable.

The peripheral speed of the tip of the agitation blades 21 in the washing step (Step (S2)) is not particularly limited, and is preferably equal to or greater than 1 m/s and equal to or lower than 15 m/s. The upper limit value is more preferably 12 m/s, particularly preferably 10 m/s, and most preferably 8 m/s.

The time length of the washing step (Step (S2)) is not particularly limited, and is preferably equal to or greater than 5 minutes up to 30 minutes. The lower limit value is more preferably 10 minutes. The upper limit value is more preferably 20 minutes.

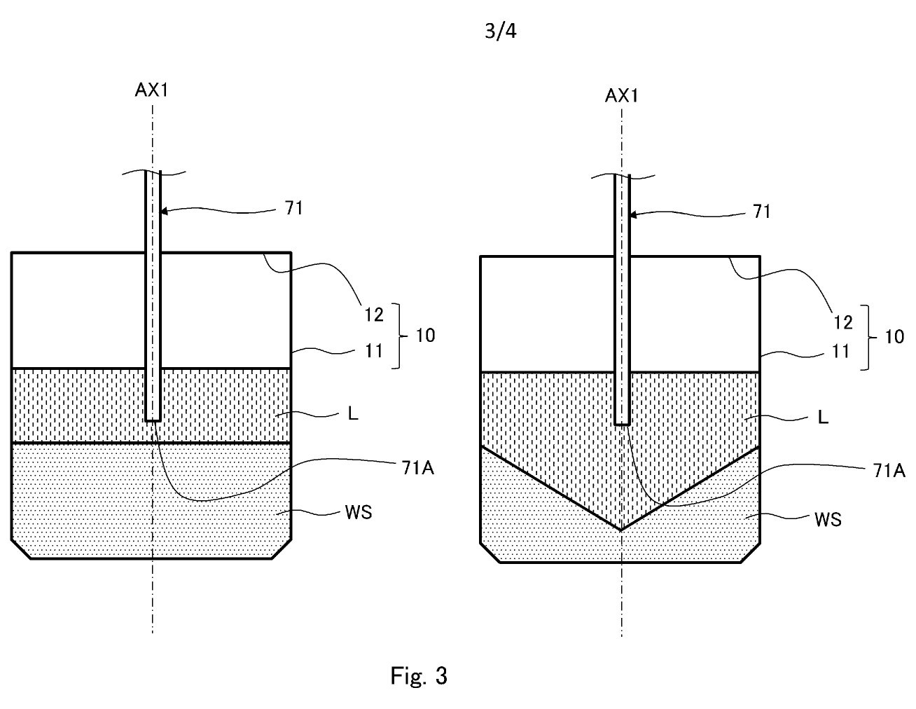

In the case where the agitating apparatus 20 is stopped after the end of the washing step (Step (S2)), foundry sand has a large specific gravity with respect to the aqueous medium and the frictional force between sand particles is large, so that foundry sand can settle in the vessel 10 due to gravity. As a result, as shown in the left-side drawing in FIG. 3, wet foundry sand WS containing settled foundry sand and the aqueous medium in which a water-soluble binder is dissolved can be formed on the lower side of the vessel 10. Further, a supernatant liquid L (liquid phase) consisting of the aqueous medium in which a water-soluble binder is dissolved and containing no foundry sand can be formed on the wet foundry sand WS.

In the case where the agitating apparatus 20 is operated at a low speed after the washing step (Step (S2)) ends, foundry sand has a large specific gravity with respect to the aqueous medium and the frictional force between the sand particles is large, so that foundry sand can be deposited in a mortar shape in the vessel 10 due to gravity and centrifugal force. As a result, as shown in the right-side drawing in FIG. 3, a mortar-shaped wet foundry sand WS containing the aqueous medium in which foundry sand and a water-soluble binder are dissolved can be formed on the lower side of the vessel 10. Further, a supernatant liquid L (liquid phase) consisting of the aqueous medium in which a water-soluble binder is dissolved and containing no foundry sand can be formed in the concave part of the mortar-shaped wet foundry sand WS. Further, a supernatant liquid L (liquid phase) consisting of the aqueous medium in which a water-soluble binder is dissolved can be formed thereon.

In the present embodiment, as described above, by utilizing the difference in specific gravity between foundry sand and the aqueous medium, solid-liquid phase separation can be performed in the vessel 10 by a simple operation of stopping the agitating apparatus 20 or operating it at a low speed after completion of the washing step (Step (S2)).

It should be noted that the “low-speed operation” herein refers to an operation at an agitation speed lower than the agitation speed in the washing step (Step (S2)).

The foundry sand reclamation apparatus 1 includes a drainage apparatus 70 configured to perform draining of at least a portion of the liquid component from a mixture of the foundry sand composition and the aqueous medium present in the vessel 10 after performing agitation and mixing of the foundry sand composition and the aqueous medium charged into the vessel 10.

Here, “liquid component” includes the aqueous medium and the water-soluble binder dissolved therein.

The drainage apparatus 70 may include a drainage pipe 71 partially inserted into the vessel 10 and a drainage pump 72 connected to the drainage pipe 71.

The drainage pipe 71 includes a liquid inlet 71A into which liquid enters, and a part thereof including the liquid inlet 71A is inserted into a supernatant liquid L (liquid phase) formed by stopping or performing low-speed operation of the agitating apparatus 20 and consisting of an aqueous medium in which a water-soluble binder is dissolved. The liquid inlet 71A is disposed at a position where it does not suck the foundry sand.

The liquid inlet 71A is preferably disposed at a position on the central axis AX1 of the vessel 10 (agitation axis of the agitating apparatus 20) or near the central axis AX1 of the vessel 10 (e.g., within 5 cm of the central axis AX1). The height of the liquid inlet 71A of the drainage pipe 71 may be variable, to match the height of the surface of supernatant liquid L (liquid phase).

The drainage pipe 71 preferably may extend from the inside of the vessel 10, through the upper lid 12 of the vessel 10, and to the outside of the vessel 10.

The drainage pipe 71 may be configured of a metal tubing, hoses, or a combination thereof.

The drainage apparatus 70 may also optionally include at least one other element, such as valves and flow meters.

In the foundry sand reclamation apparatus 1, the drainage apparatus 70 performs a draining step (Step (S3)) of performing draining of at least a portion of the liquid component from a mixture of the foundry sand composition and the aqueous medium present in the vessel 10 after agitation and mixing of the foundry sand composition and the aqueous medium charged into the vessel 10 are performed. By this operation, it is possible to perform a separation step of separating and removing most of the aqueous medium in which a water-soluble binder is dissolved from the mixture of the foundry sand composition and the aqueous medium charged into the vessel 10.

In the method according to the present embodiment, most of the aqueous medium in which a water-soluble binder is dissolved can be separated and removed by a simple operation of solid-liquid phase separation and draining without taking out wet sand from the vessel 10 and without using a separation apparatus such as a filter.

However, if necessary, a known filter may be disposed at or near the liquid inlet 71A of the drainage pipe 71 to prevent foundry sand from being sucked into the drainage pipe 71.

The draining step (Step (S3)) may be implemented without agitating the content of the vessel 10 (a mixture of a foundry sand composition and an aqueous medium), or the draining step (Step (S3)) may be implemented while the content of the vessel 10 (a mixture of a foundry sand composition and an aqueous medium) is being agitated at a low speed using the agitating apparatus 20.

The circumferential velocity of the distal end of the agitation blades 21 in the draining step (Step (S3)) is not particularly limited, and is preferably 1/2 or lower, more preferably equal to or lower than 1/3, particularly preferably equal to or lower than 1/5, and most preferably equal to or lower than 1/8 of the circumferential velocity of the distal end of the agitation blades 21 in the washing step (Step (S2)).

The circumferential velocity of the distal end of the agitation blades 21 in the draining step (Step (S3)) is preferably equal to or greater than 0 m/s and equal to or lower than 1.5 m/s. The lower limit value is more preferably 0.1 m/s. The upper limit is more preferably 1.2 m/s, particularly preferably 1.0 m/s, and most preferably 0.8 m/s.

From the viewpoint of improving the removal efficiency of a water-soluble binder, it is preferable to implement the draining step (Step (S3)) while the temperature inside the vessel 10 is being heated or controlled using the heating or temperature control apparatus 81. The temperature inside the vessel 10 during implementation of the draining step (Step (S3)) is not particularly limited, and is preferably equal to or greater than 40℃ and equal to or lower than 100℃. The lower limit is more preferably 50℃, more preferably 60℃, further more preferably 70℃, particularly preferably 80℃, and most preferably 90℃. The upper limit is more preferably 99℃, furthermore preferably 98℃, particularly preferably 97℃, and most preferably 95℃.

The time length of the draining step (Step (S3)) is not particularly limited, and is preferably equal to or greater than 1 minute up to 15 minutes. The lower limit is more preferably 2 minutes. The upper limit is more preferably 10 minutes, and particularly preferably 5 minutes.

After the draining step (Step (S3)), residue (wet foundry sand WS) including the foundry sand and the liquid component which cannot be drained remains in the vessel 10.

The water content in the residue (wet foundry sand WS) remaining in the vessel 10 after the draining step (Step (S3)) is not particularly limited, and may be equal to greater than 10 mass% and equal to or lower than 30 mass% with respect to 100 mass% foundry sand. The lower limit value may be 12 mass% or 15 mass%. The upper limit value is preferably 25 mass%, and more preferably 20 mass%.

The foundry sand reclamation apparatus 1 is provided with a drying apparatus 80 for drying residue (wet foundry sand WS) including the foundry sand remaining in the vessel 10 after the draining step (Step (S3)).

In the foundry sand reclamation apparatus 1, a drying step (Step (S4)) for drying residue (wet foundry sand WS) including the foundry sand remaining in the vessel 10 after the draining step (Step (S3)) is performed. By this operation, liquid component is removed by drying, and reclaimed foundry sand is obtained.

The drying method includes heat drying, decompression drying, and decompression heat drying.

For performing heat drying, the drying apparatus 80 may include the heating or temperature control apparatus 81 for heating or controlling the temperature inside the vessel 10.

For performing decompression drying, the drying apparatus 80 may include a decompression apparatus 82 configured to perform decompression inside the vessel 10. The decompression apparatus 82 may include an exhaust pipe 82A connected to the vessel 10 and a vacuum pump 82B connected to the exhaust pipe 82A. The decompression apparatus 82 may optionally include at least one other element such as a valve, a pressure gauge, and a heat exchanger.

For performing decompression heat drying, the drying apparatus 80 may include the heating or temperature control apparatus 81 described above and the decompression apparatus 82 described above.

A known heating or temperature control apparatus may be used for the heating or temperature control apparatus 81. The heating or temperature control apparatus 81 may include, for example, a jacket covering at least a part of the vessel main body 11 and allowing fluid such as cold water, hot water, steam, and oil to flow therein, and optionally a temperature control apparatus for controlling the temperature of the fluid flowing within the jacket by a well-known method. By selecting the temperature of the fluid flowing within the jacket, the temperature inside the vessel 10 can be heated, controlled, or cooled.

Decompression drying or decompression heat drying does not require high-temperature heating, and the cooling step after the drying step can be eliminated or shortened, which is preferable.

For example, in the case where decompression heat drying is performed under a reduced pressure of equal to or lower than 95 kPa, drying can be performed at a relatively low temperature of equal to or greater than 30℃ and equal to or lower than 50℃.

From the viewpoint of improving drying efficiency, it is preferable to implement the drying step (Step (S4)) while the residue is being agitated using the agitating apparatus 20.

The peripheral speed of the tip of the agitation blades 21 in the drying step (Step (S4)) is not particularly limited, and is preferably equal to or greater than 1 m/s and equal to or lower than 15 m/s. The upper limit value is more preferably 12 m/s, particularly preferably 10 m/s, and most preferably 8 m/s.

In the case where the drying step (Step (S4)) is implemented while the residue is being agitated using the agitating apparatus 20, the foundry sand can be polished by collision of the foundry sand with each other under the presence of moderate moisture (hereinafter referred to as polishing treatment).

The polishing treatment of foundry sand can smooth the surface of the foundry sand and improve the strength of the mold in which the reclaimed foundry sand is used, which is preferable.

At the start of the drying step (Step (S4)), a small amount of water-soluble binder may remain on the surface of foundry sand. Even in this case, it is preferable that a small amount of water-soluble binder remaining on the surface of foundry sand can be physically removed by the polishing treatment of the foundry sand.

It is to be noted that Patent Literature 1 mentioned in the [Background] section does not disclose a technique for efficiently implementing the washing step, the separation step and the drying step in one vessel. This document also does not disclose a technique of performing the drying step while the residue is being agitated. The drying step in this document also serves as a polishing step, and the effect of smoothing the surface of the foundry sand and physically removing a small amount of water-soluble binder remaining on the surface of the foundry sand cannot be obtained in the drying step.

The drying step (Step (S4)) is implemented until the water content in the reclaimed foundry sand becomes an amount suitable for manufacturing a mold.

The water content in the wet foundry sand at the start of the drying step (Step (S4)) is not particularly limited, and may be equal to or greater than 10 mass% and equal to lower than 30 mass% based on 100 mass% foundry sand.

The water content in the reclaimed foundry sand obtained after the completion of the drying step (Step (S4)) is not particularly limited, and is preferably equal to or greater than 0 mass% and equal to or lower than 1.0 mass% based on 100 mass% foundry sand. The upper limit is more preferably 0.9 mass%, further more preferably 0.8 mass%, particularly preferably 0.7 mass%, and most preferably 0.5 mass%. The lower limit value may be 0.05 mass% or 0.1 mass%.

The time length of the drying step (Step (S4)) is not particularly limited, and is preferably equal to or greater than 15 minutes up to 60 minutes. The lower limit value is more preferably 20 minutes. The upper limit value is more preferably 50 minutes, and particularly preferably 40 minutes.

In the case where the drying step (Step (S4)) is performed while the residue is being agitated using the agitating apparatus 20 as described above, while the drying step (Step (S4)) is being implemented, the drying step (Step (S4)) can also serve as the polishing step while moderate moisture is present.

For example, the drying step (Step (S4)) can also serve as the polishing step while the water content relative to 100 mass% of foundry sand is preferably equal to or greater than 5 mass% and equal to or lower than 30 mass%, more preferably equal to or greater than 6 mass% and equal to or lower than 25 mass%, and particularly preferably equal to or greater than 6 mass% to equal to or lower than 20 mass%.

In the foundry sand reclamation apparatus 1 and foundry sand reclamation method using the same, a different known-polishing treatment may be implemented after the drying step (Step (S4)) alternatively or additionally to the above-described method. In this case also, the different polishing treatment can be performed in the same the vessel 10.

The reclaimed foundry sand obtained after the drying step (Step (S4)) can be cooled in the vessel 10, if necessary. The cooling method may be natural cooling or forced cooling using the heating or temperature control apparatus 81.

The processing apparatus 2 may include a discharge unit 40 for discharging the final reclaimed foundry sand. The discharge unit 40 includes a discharge port 41 and an open/close valve 42 for opening and closing the discharge port 41, and may further include a discharge channel 43 as needed. The discharge port 41 may be provided at a low position on the side of the vessel main body 11. The discharge channel 43 may extend obliquely downward from the discharge port 41.

In the foundry sand reclamation apparatus 1, by opening the open/close valve 42 and opening the discharge port 41, a discharge step (Step (S5)) for discharging the final reclaimed foundry sand to the outside through the discharge port 41 and the discharge channel 43 can be implemented.

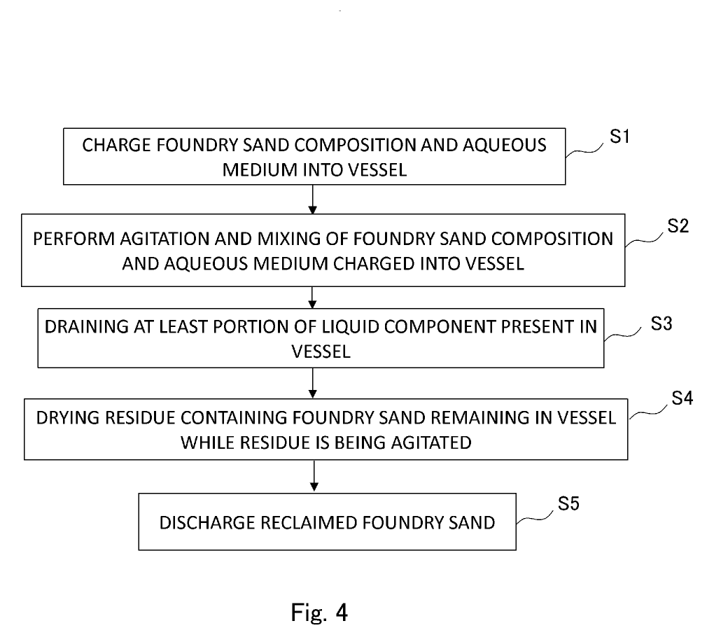

As shown in a flowchart in FIG. 4,
a foundry sand reclamation method of the present disclosure includes:
a step (S1) of charging a foundry sand composition and an aqueous medium into the vessel 10;
a step (S2) of performing agitation and mixing of the foundry sand composition and the aqueous medium charged into the vessel 10;
a step (S3) of performing draining of at least a portion of the liquid component from a mixture of the foundry sand composition and the aqueous medium present in the vessel 10 after the step (S2); and
a step (S4) of drying a residue containing the foundry sand remaining in the vessel 10 after the step (S3) while the residue is being agitated.

A small amount of water-soluble binder may adhere to the foundry sand after the step (S3) is implemented. Therefore, in order to remove the remaining water-soluble binder, the aqueous medium may be re-charged into the vessel 10 after the step (S3), and the step (S2) and the step (S3) may be implemented again (i.e., repeated), if necessary. Further, if necessary, the re-charging of the aqueous medium and the re-implementation of the step (S2) and the step (S3) may be repeated at least once.

In the foundry sand reclamation method of the present disclosure, the step (S4) may also serve as a step of performing polishing treatment.

The foundry sand reclamation method of the present disclosure may optionally include a step of performing a known polishing treatment after the step (S4).

The foundry sand reclamation method of the present disclosure may optionally include a step of cooling the obtained reclaimed foundry sand in the vessel 10 after the step (S4).

The foundry sand reclamation method of the present disclosure may include a step (S5) of discharging the reclaimed foundry sand obtained from the vessel 10 as a final step.

According to the foundry sand reclamation apparatus 1 and the foundry sand reclamation method of the present disclosure, the washing step, the separation step, and the drying step can be efficiently implemented in one vessel 10.

According to the technique of the present disclosure, it is not necessary to take out the wet sand containing the aqueous medium having poor handling properties from the vessel after the washing step, and work that consume time, labor, and cost, such as taking out the wet sand from the vessel and conveying the wet sand for the next step, are unnecessary.

According to the technique of the present disclosure, the polishing treatment of the foundry sand can be performed simultaneously with the drying step and/or after the drying step in the same vessel 10, as necessary.

According to the technique of the present disclosure, the obtained reclaimed foundry sand can be cooled in the same vessel 10, as necessary.

According to the technique of the present disclosure, all the steps necessary for reclaiming foundry sand from a foundry sand composition containing a foundry sand and a water-soluble binder can be efficiently implemented in one vessel 10.

As described above, according to the present embodiment, it is possible to provide a foundry sand reclamation apparatus and a foundry sand reclamation method each adapted to efficiently implement a washing step, a separation step, and a drying step.

The present disclosure is not limited to the above-described embodiments, and the design thereof can be modified appropriately without departing from the spirit of the present disclosure.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A foundry sand reclamation apparatus for reclaiming foundry sand from a foundry sand composition containing foundry sand and a water-soluble binder, comprising:
a vessel into which the foundry sand composition and an aqueous medium are charged;
an agitating apparatus configured to perform agitation and mixing of the foundry sand composition and the aqueous medium charged into the vessel;
a drainage apparatus configured to perform draining of at least a portion of the liquid component from a mixture of the foundry sand composition and the aqueous medium present in the vessel after agitation and mixing thereof are performed; and
a drying apparatus configured to perform drying of a residue including the foundry sand remaining in the vessel after the draining is performed, the drying apparatus including a heating or temperature control apparatus configured to perform heating or controlling of a temperature inside the vessel and/or a decompression apparatus configured to perform decompression inside the vessel, wherein
the drying apparatus performs drying of the residue while the residue is being agitated using the agitating apparatus.

2. The foundry sand reclamation apparatus according to claim 1, wherein after the foundry sand composition and the aqueous medium are agitated and mixed using the agitating apparatus, the foundry sand composition and the aqueous medium present in the vessel thereafter are subjected to solid-liquid phase separation, and the liquid component is drained from a liquid phase obtained by performing the solid-liquid phase separation.

3. The foundry sand reclamation apparatus according to claim 2, wherein
the drainage apparatus includes a drainage pipe partially inserted into the vessel and a drainage pump connected to the drainage pipe,
a liquid inlet of the drainage pipe is inserted into the liquid phase obtained by performing the solid-liquid phase separation.

4. A foundry sand reclamation method for reclaiming foundry sand from a foundry sand composition containing foundry sand and a water-soluble binder, comprising:
a step (S1) of performing charging of the foundry sand composition and an aqueous medium into a vessel;
a step (S2) of performing agitation and mixing of the foundry sand composition and the aqueous medium charged into vessel;
a step (S3) of performing draining of at least a portion of the liquid component from a mixture of the foundry sand composition and the aqueous medium present in the vessel after the step (S2); and
a step (S4) of performing drying of a residue containing the foundry sand remaining in the vessel after the step (S3) while the residue is being agitated.

5. The method for reclaiming the foundry sand according to claim 4,
wherein, after the step (S2), the agitation performed by the agitating apparatus is stopped or the agitating apparatus is operated at a low speed, to thereby perform solid-liquid phase separation of the mixture of the foundry sand composition and the aqueous medium present in the vessel after the step (S2),
wherein in the step (S3), drainage of the liquid component from the liquid phase obtained by performing solid-liquid phase separation is performed.
